(19) United States
(12) Patent Application Publication
(10) Pub. No.: US 2025/0210446 A1
(43) Pub. Date: Jun. 26, 2025

(54) INTEGRATED CIRCUIT AND MANUFACTURING METHOD THEREOF

(71) Applicant: Taiwan Semiconductor Manufacturing Company, Ltd., Hsinchu (TW)

(72) Inventors: Isha Datye, Hsinchu (TW); Sam Vaziri, San Jose, CA (US); Xinyu BAO, Fremont, CA (US)

(73) Assignee: Taiwan Semiconductor Manufacturing Company, Ltd., Hsinchu (TW)

(21) Appl. No.: 18/391,453

(22) Filed: Dec. 20, 2023

(51) Int. Cl. H01L 23/373; H01L 21/02; H01L 23/522; H01L 23/528

(52) U.S. Cl. CPC H01L 23/3735; H01L 21/02115; H01L 23/5226; H01L 23/5283

(57) ABSTRACT

An integrated circuit includes a semiconductor substrate and an interconnect structure. The interconnect structure is disposed on the semiconductor substrate. The interconnect structure includes a signal transmission structure and a heat dissipation structure. The heat dissipation structure is disposed on the signal transmission structure and includes a composite dielectric layer and first conductive features. The composite dielectric layer includes an adhesive layer and a diamond layer disposed on the adhesive layer. The first conductive features are embedded in the composite dielectric layer.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1Q are schematic cross-sectional views illustrating a manufacturing process of an integrated circuit in accordance with some embodiments of the disclosure.

FIG. 2A to FIG. 2C are schematic cross-sectional views illustrating intermediate stages of a manufacturing process of an integrated circuit in accordance with some alternative embodiments of the disclosure.

FIG. 3 is a schematic cross-sectional view of an integrated circuit in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

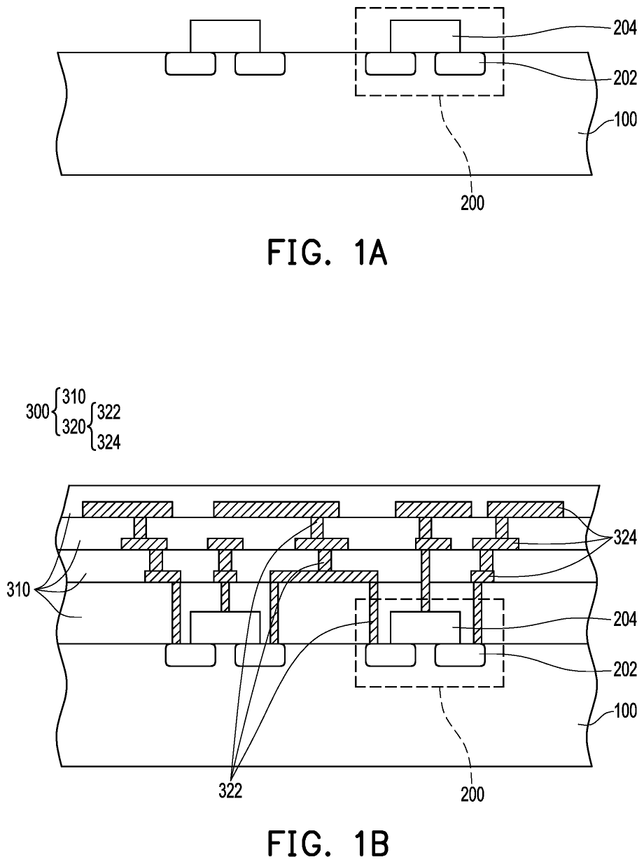

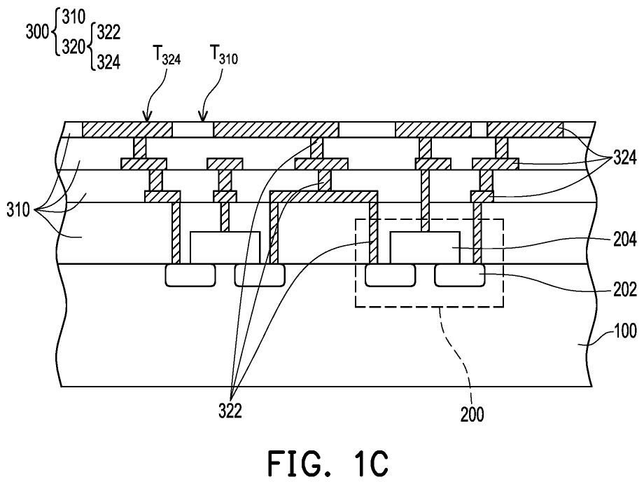

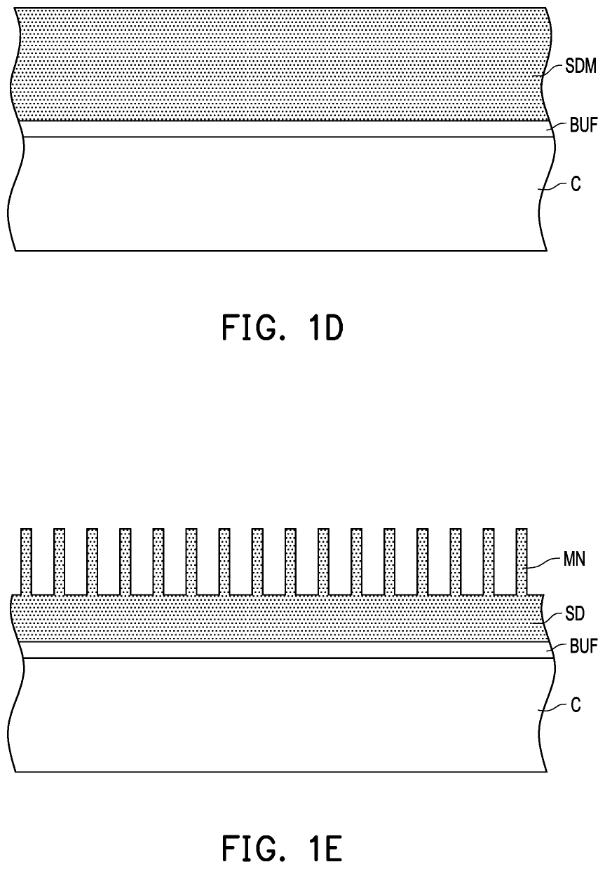

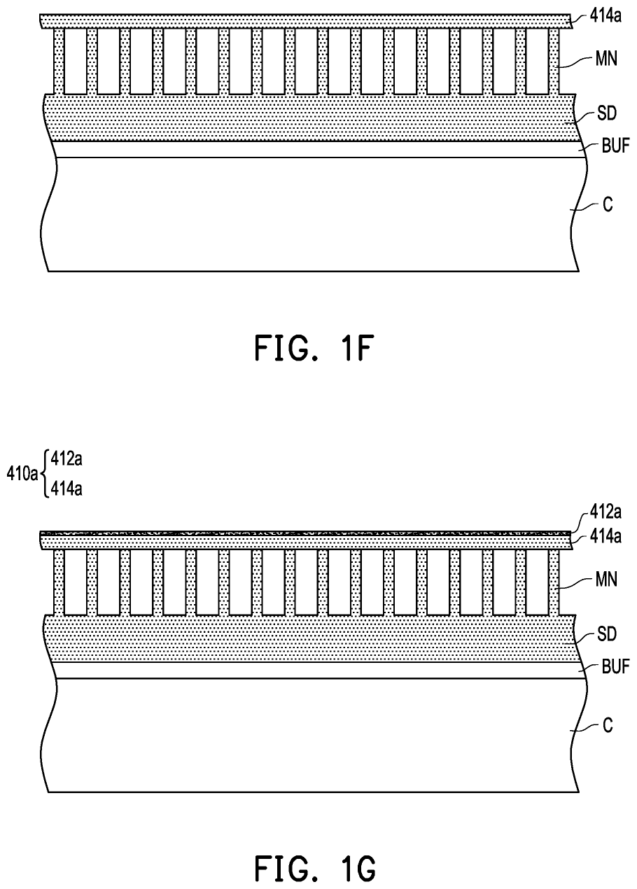

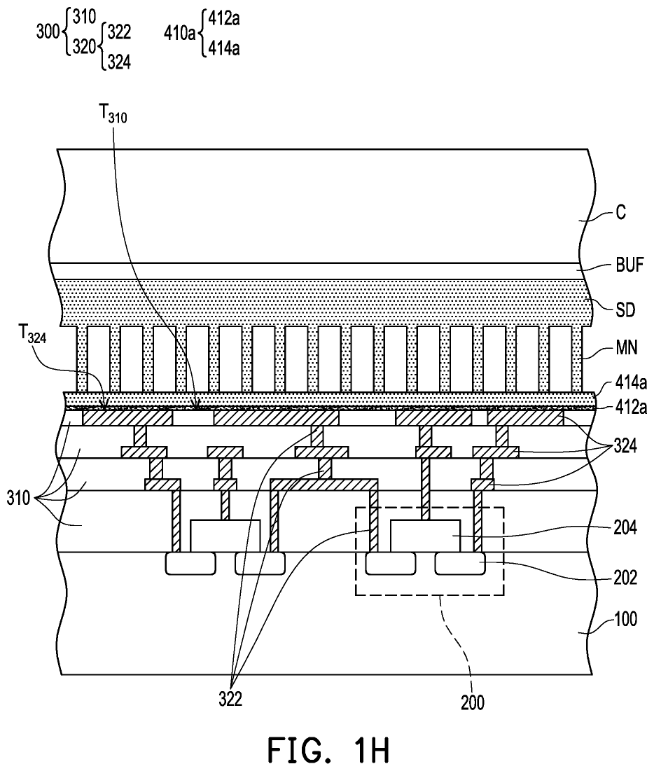

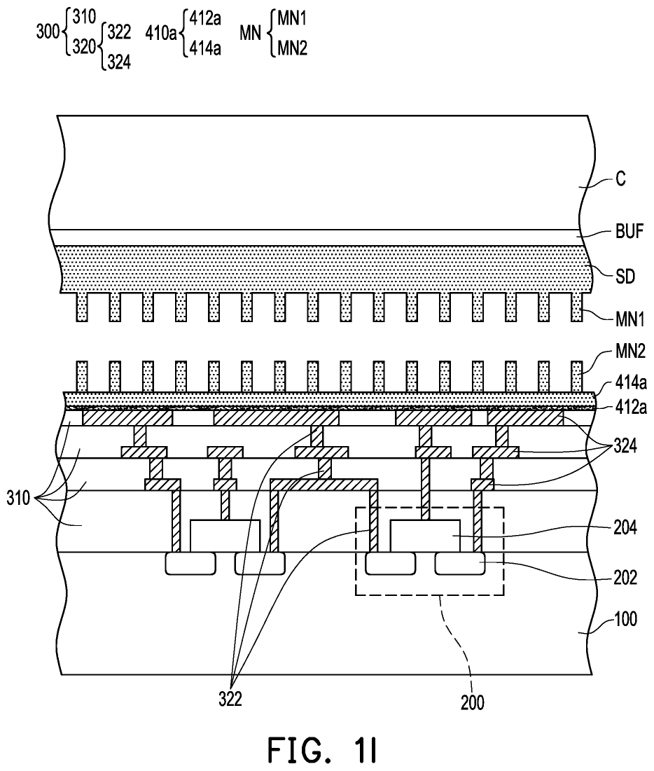

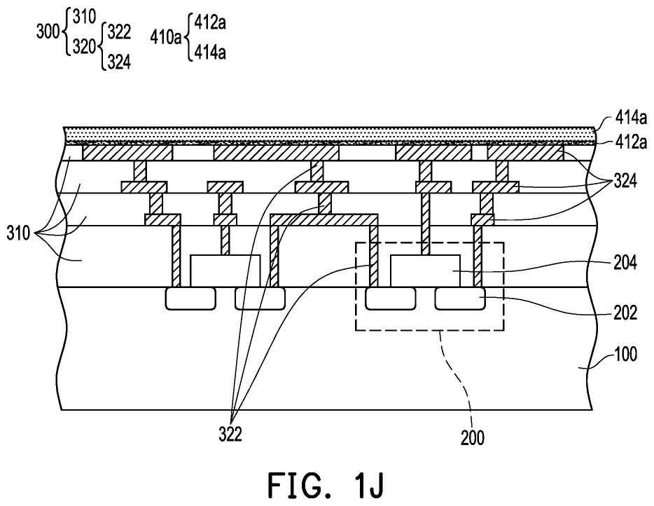

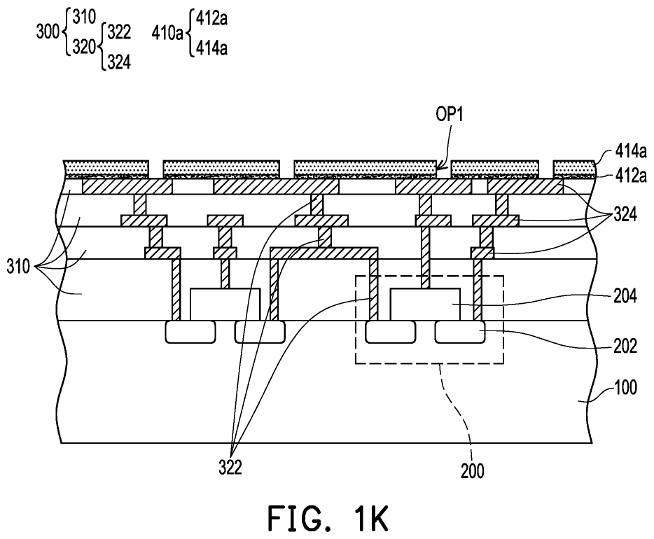

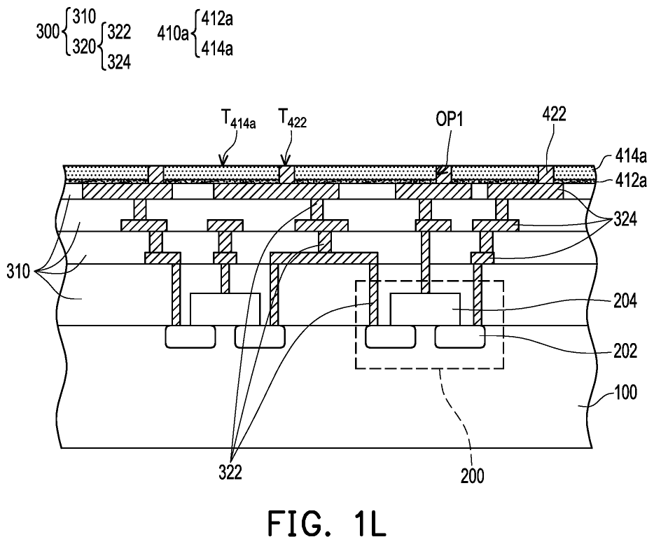

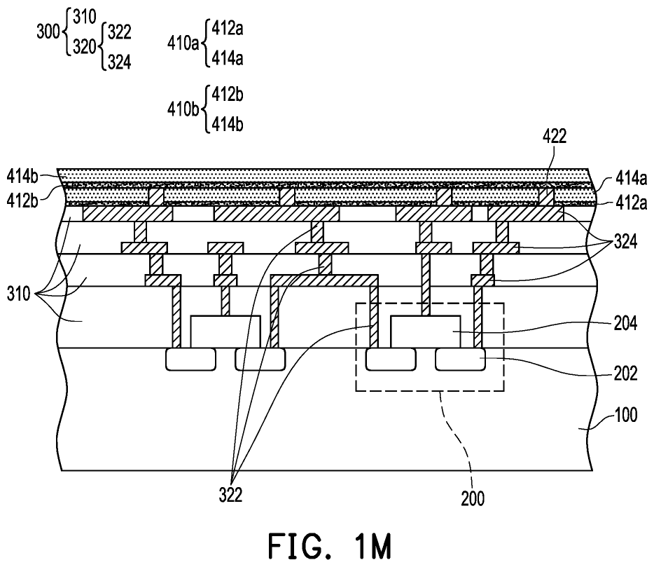

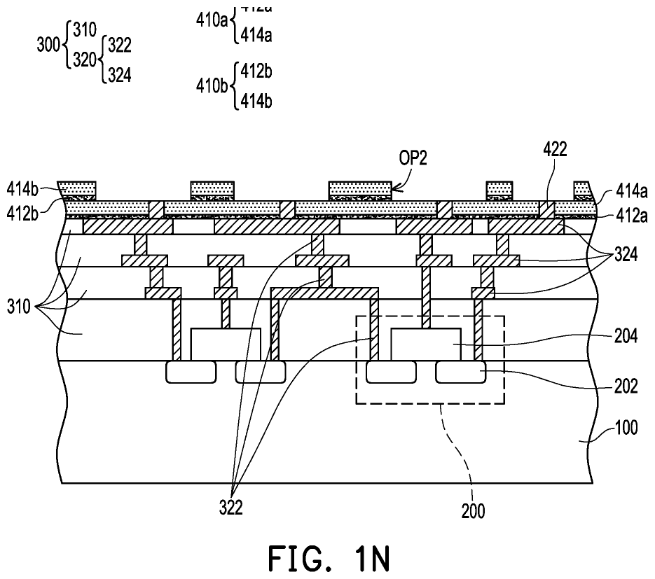

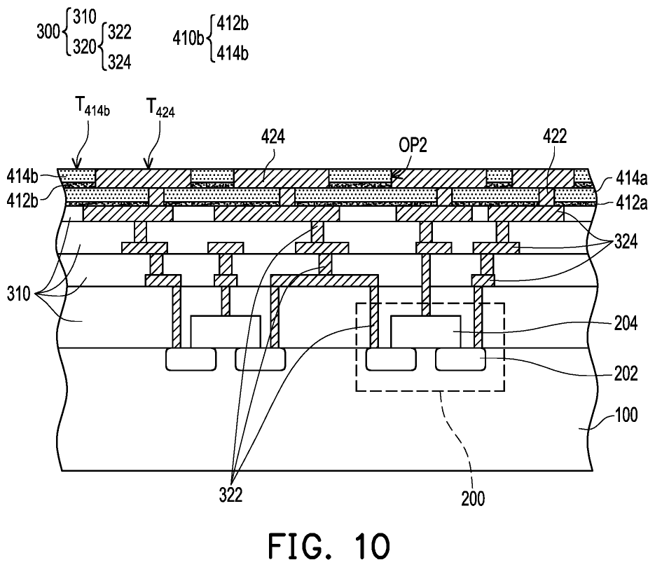

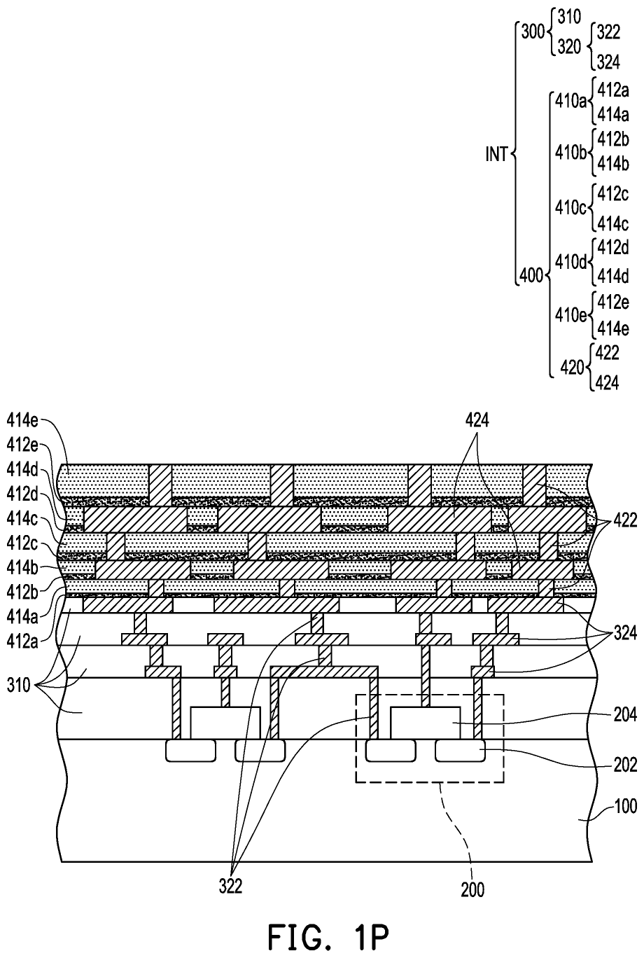

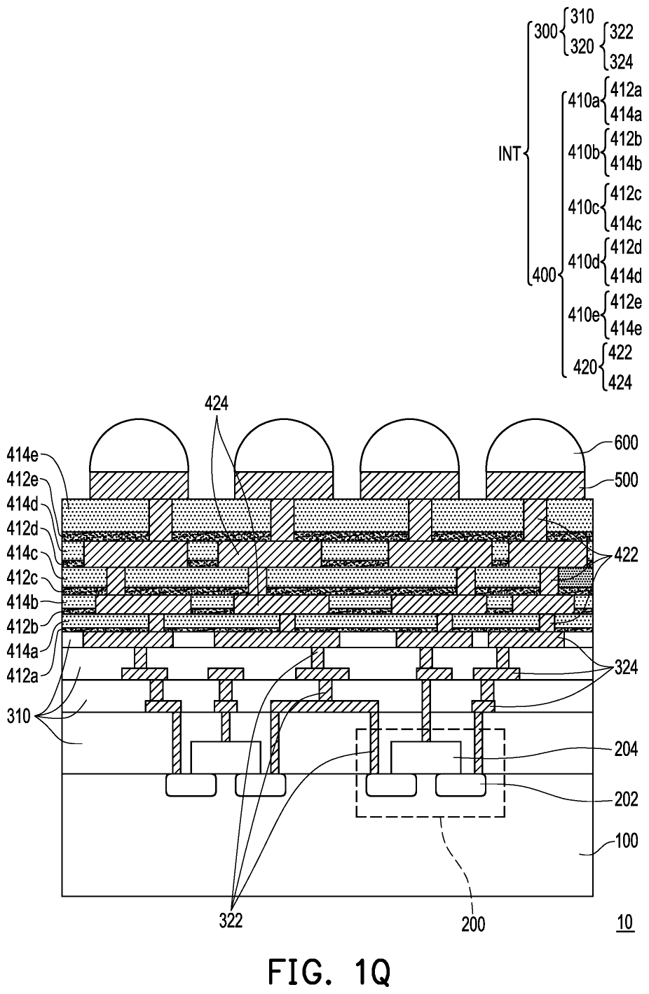

FIG. 1A to FIG. 1Q are schematic cross-sectional views illustrating a manufacturing process of an integrated circuit 10 in accordance with some embodiments of the disclosure. Referring to FIG. 1A, a semiconductor substrate 100 is provided. In some embodiments, the semiconductor substrate 100 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The semiconductor substrate 100 may be a bulk silicon substrate, a silicon-on-insulator (SOI) substrate, or a germanium-on-insulator (GOI) substrate.

As illustrated in FIG. 1A, a plurality of transistors 200 is formed on the semiconductor substrate 100. In some embodiments, each transistor 200 includes source/drain regions 202 and a gate electrode 204. In some embodiments, each transistor 200 further includes a channel region (not shown) under the gate electrode 204. In some embodiments, the channel region is also located between the source/drain regions 202 to serve as a path for electron to travel when the transistor 200 is turned on.

In some embodiments, the semiconductor substrate 100 includes various doped regions depending on circuit requirements (e.g., p-type semiconductor substrate or n-type semiconductor substrate). In some embodiments, the doped regions are doped with p-type or n-type dopants. For example, the doped regions may be doped with p-type dopants, such as boron or BF₂; n-type dopants, such as phosphorus or arsenic; and/or combinations thereof. In some embodiments, these doped regions serve as the source/drain regions 202 of the transistors 200. Depending on the types of the dopants in the doped regions, the transistors 200 may be referred to as n-type transistors or p-type transistors.

In some embodiments, the gate electrode 204 includes copper, titanium, tantalum, tungsten, aluminum, zirconium, hafnium, cobalt, titanium aluminum, tantalum aluminum, tungsten aluminum, zirconium aluminum, hafnium aluminum, titanium nitride, any other suitable metal-containing material, or a combination thereof. In some embodiments, the gate electrode 204 also includes materials to fine-tune the corresponding work function. For example, the gate electrode 204 may also include p-type work function materials such as Ru, Mo, WN, ZrSi₂, MoSi₂, TaSi₂, NiSi₂, or combinations thereof, or n-type work function materials such as Ag, TaCN, Mn, or combinations thereof.

As illustrated in FIG. 1A, the source/drain regions 202 are embedded in the semiconductor substrate 100 and the gate electrode 204 is located above the semiconductor substrate 100. However, the disclosure is not limited thereto. In some alternative embodiments, the source/drain regions 202 and the gate electrode 204 are both located above the semiconductor substrate 100. In some embodiments, the transistors 200 may be separated by shallow trench isolation (STI; not shown) located between two adjacent transistors 200. In some embodiments, the transistors 200 are formed using suitable Front-end-of-line (FEOL) process.

Referring to FIG. 1B, a signal transmission structure 300 is formed on the semiconductor substrate 100 and the transistors 200. In some embodiments, the signal transmission structure 300 includes a plurality of dielectric layers 310 and a plurality of conductive features 320. In some embodiments, the dielectric layers 310 are stacked on one another. For example, the adjacent dielectric layers 310 are in physical contact with each other. In some embodiments, a material of the dielectric layers 310 includes polyimide, epoxy resin, acrylic resin, phenol resin, benzocyclobutene (BCB), polybenzooxazole (PBO), or any other suitable polymer-based dielectric material. Alternatively, the dielectric layers 310 may be formed of oxides or nitrides, such as silicon oxide, silicon nitride, hafnium oxide, hafnium zirconium oxide, or the like. In some embodiments, different dielectric layers 310 are formed by the same material. However, the disclosure is not limited thereto. In some alternative embodiments, different dielectric layers 310 may be formed by different materials. The dielectric layers 310 may be formed by suitable fabrication techniques, such as spin-on coating, chemical vapor deposition (CVD), plasma-enhanced chemical vapor deposition (PECVD), or the like. In some embodiments, a number of the dielectric layers 310 is four or more.

In some embodiments, the conductive features 320 include a plurality of conductive structures 322 and a plurality of conductive patterns 324. As illustrated in FIG. 1B, the conductive features 320 are embedded in the dielectric layers 310. That is, the conductive structures 322 and the conductive patterns 324 are embedded in the dielectric layers 310. For example, the dielectric layers 310 laterally encapsulate the conductive structures 322 and the conductive patterns 324. In some embodiments, the conductive patterns 324 extend horizontally. Meanwhile, the conductive structures 322 extend vertically to connect the conductive patterns 324 located at different level heights. In other words, the conductive patterns 324 are electrically connected to one another through the conductive structures 322. In some embodiments, the bottommost conductive structures 322 are connected to the transistors 200. For example, the bottommost conductive structures 322 are connected to the source/drain regions 202 and the gate electrodes 204 of the transistors 200. In other words, the bottommost conductive structures 322 establish electrical connection between the transistors 200 and the conductive patterns 324. That is, the conductive features 320 are electrically connected to the transistors 200. In some embodiments, the conductive structures may be referred to as “conductive vias.” In some alternative embodiments, the bottommost conductive structures 322 may be referred to as “contact structures” of the transistors 200.

In some embodiments, a material of the conductive patterns 324 and the conductive structures 322 includes aluminum, titanium, copper, nickel, tungsten, or alloys thereof. The conductive patterns 324 and the conductive structures 322 may be formed by electroplating, deposition, and/or photolithography and etching. In some embodiments, the conductive patterns 324 and the underlying conductive structures 322 are separately formed. However, the disclosure is not limited thereto. In some alternative embodiments, the conductive patterns 324 and the underlying conductive structures 322 may be formed simultaneously. As illustrated in FIG. 1B, the conductive structures 322 and the underlying conductive patterns 324 are embedded in the same dielectric layer 310. In other words, a top surface of each conductive structure 322 is coplanar with a top surface of the corresponding dielectric layer 310. Meanwhile, a top surface of each conductive pattern 324 is located at a level height lower than that of the top surface of the corresponding dielectric layer 310. That is, the top surfaces of the conductive patterns 324 are covered by the dielectric layers 310.

Referring to FIG. 1B and FIG. 1C, a planarization process is performed on the topmost dielectric layer 310 until the topmost conductive patterns 324 are revealed. That is, after the planarization process, top surfaces T₃₂₄ of the topmost conductive patterns 324 are coplanar with a top surface T₃₁₀ of the topmost dielectric layer 310. In some embodiments, the planarization process reduces a surface roughness of the top surfaces T₃₂₄ of the topmost conductive patterns 324 and a surface roughness of the top surface T₃₁₀ of the topmost dielectric layer 310 to less than 1 nm. In some embodiments, the planarization process includes a mechanical grinding process, a chemical mechanical polishing (CMP) process, or the like.

Referring to FIG. 1D, a carrier substrate C is provided. In some embodiments, the carrier substrate C is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The carrier substrate C may be a bulk silicon substrate, a SOI substrate, a GOI substrate, or the like. In certain embodiments, the material of the carrier substrate C includes silicon, silicon nitride, sapphire, SrTiO₃, MgO, or the like.

In some embodiments, a buffer layer BUF is formed on the carrier substrate C. In some, a material of the buffer layer BUF includes iridium or the like. The buffer layer BUF may be formed on the carrier substrate C through e-beam evaporation, magnetron sputtering, metal-organic CVD, atomic layer deposition (ALD), pulsed laser deposition, or the like. In some embodiments, the process temperature for forming the buffer layer BUF is 850° C. or higher.

After the buffer layer BUF is formed on the carrier substrate C, a sacrificial diamond material layer SDM is grown on the buffer layer BUF and the carrier substrate C. In some embodiments, the sacrificial diamond material layer SDM is formed on the buffer layer BUF and the carrier substrate C through CVD, microwave plasma chemical vapor deposition (MPCVD), or the like. In some embodiments, the process temperature for growing the sacrificial diamond material layer SDM is 700° C. or higher. In some embodiments, the sacrificial diamond material layer SDM is considered to be heteroepitaxial grown on the buffer layer BUF and the carrier substrate C. In some embodiments, the buffer layer BUF is able to effectively improve the quality of the sacrificial diamond material layer SDM formed thereon. For example, as compared to a scenario without a buffer layer, carbon atoms are able to enter the surface of the buffer layer BUF at a higher molar fraction (for example, 10%) during the growing process of the sacrificial diamond material layer SDM. Therefore, more carbon sources can be provided to form high-density diamond nucleation sites on the surface of the buffer layer BUF, and the epitaxial growth of the sacrificial diamond material layer SDM may be sufficiently improved.

Referring to FIG. 1D and FIG. 1E, the sacrificial diamond material layer SDM is patterned to form a sacrificial diamond layer SD having microneedles MN thereon. In some embodiments, the patterning process includes a photolithography process and an etching process. The etching process includes a dry etching process. For example, the sacrificial diamond material layer SDM may be patterned through reactive ion etch (RIE), inductively coupled plasma (ICP) etch, electron cyclotron resonance (ECR) etch, neutral beam etch (NBE), or the like. In some embodiments, oxygen may be used as an etching gas during the dry etching process. In some embodiments, the microneedles MN are arranged in an array. Although FIG. 1E illustrated that each of the microneedles MN has upright sidewalls, the disclosure is not limited thereto. In some alternative embodiments, each of the microneedles MN may have slanted sidewalls and a pointy tip.

Referring to FIG. 1F, a diamond layer 414a is grown on the microneedles MN. For example, the microneedles MN may serve as seed layers for the epitaxial growth of the diamond layer 414a. In some embodiments, the diamond layer 414a is grown on the microneedles MN through CVD, MPCVD, or the like. Similar to that of the sacrificial diamond material layer SDM, the process temperature for growing the diamond layer 414a is also 700° C. or higher. As illustrated in FIG. 1F, the microneedles MN are sandwiched between the sacrificial diamond layer SD and the diamond layer 414a.

Referring to FIG. 1G, an adhesive layer 412a is formed on the diamond layer 414a. In some embodiments, a material of the adhesive layer 412a includes a metal oxide or a metal nitride. For example, the material of the adhesive layer 412a includes aluminum oxide or aluminum nitride. However, the disclosure is not limited thereto. In some alternatively embodiments, other materials having adhesion properties may also be applicable as materials for the adhesive layer 412a. In some embodiments, the adhesive layer 412a is formed by suitable fabrication techniques, such as spin-on coating, CVD, PECVD, or the like. In some embodiments, after the adhesive layer 412a is formed on the diamond layer 414a, a planarization process is performed on the adhesive layer 412a to reduce a surface roughness thereof. In some embodiments, a thickness of the adhesive layer 412a is 30 nm or less. For example, the thickness of the adhesive layer 412a may range between about 1 nm to about 30 nm. In some embodiments, since both of the adhesive layer 412a and the diamond layer 414a are made of dielectric materials, the adhesive layer 412a and the diamond layer 414a may be collectively referred to as a composite dielectric layer 410a. That is, the composite dielectric layer 410a is grown over the carrier substrate C, the buffer layer BUF, the sacrificial diamond layer SD, and the microneedles MN.

Referring to FIG. 1H, the structure illustrated in FIG. 1C is combined with the structure illustrated in FIG. 1G. For example, the structure illustrated in FIG. 1G is flipped upside down and is placed onto the structure illustrated in FIG. 1C. That is, the diamond layer 414a, the microneedles MN, the sacrificial diamond layer SD, the buffer layer BUF, and the carrier substrate C are attached to the signal transmission structure 300 through the adhesive layer 412a. As illustrated in FIG. 1H, the adhesive layer 412a is in physical contact with the top surface T₃₁₀ of the topmost dielectric layer 310 and the top surfaces T₃₂₄ of the topmost conductive patterns 324. As mentioned above, the surface roughness of the top surfaces T₃₂₄ of the topmost conductive patterns 324 and the surface roughness of the top surface T₃₁₀ of the topmost dielectric layer 310 are less than 1 nm. As such, the adhesive layer 412a is attached to a substantially flat surface. In some embodiments, the material of the dielectric layers 310 is different from the material of the composite dielectric layer 410a. That is, the material of the dielectric layers 310 is different from the material of the adhesive layer 412a and the material of the diamond layer 414a. As such, an interface exits between the composite dielectric layer 410a and the topmost dielectric layer 310. That is, an interface exists between the adhesive layer 412a and the topmost dielectric layer 310.

Referring to FIG. 1H and FIG. 1I, a stress is applied to the microneedles MN, the sacrificial diamond layer SD, the buffer layer BUF, and the carrier substrate C. The stress exerted would cause the microneedles MN to crack, thereby breaking the microneedles MN into a first portion MN1 and a second portion MN2. As illustrated in FIG. 1I, the first portion MN1 of the microneedles MN is attached to the sacrificial diamond layer SD while the second portion MN2 of the microneedles MN is attached to the diamond layer 414a. In some embodiments, the breakage of the microneedles MN allows the detachment of the composite dielectric layer 410a from the sacrificial diamond layer SD, the buffer layer BUF, and the carrier substrate C. In other words, the first portion MN1 of the microneedles MN, the sacrificial diamond layer SD, the buffer layer BUF, and the carrier substrate C are detached from the second portion MN2 of the microneedles MN, the diamond layer 414a, and the adhesive layer 412a.

Referring to FIG. 1I and FIG. 1J, the microneedles MN remained on the diamond layer 414a are removed. That is, the second portion MN2 of the microneedles MN is removed. In some embodiments, the second portion MN2 of the microneedles MN is removed through an etching process, a planarization process, a combination thereof, or the like. After removing the second portion MN2 of the microneedles MN, the diamond layer 414a has a substantially flat top surface.

By performing the steps shown in FIG. 1D to FIG. 1J, the composite dielectric layer 410a can be easily grown and transferred onto the signal transmission structure 300. In some embodiments, the signal transmission structure 300 and the composite dielectric layer 410a are considered as formed during back-end-of-line (BEOL) process. Conventionally, the thermal budget (i.e., the process temperature window) for BEOL process is low. However, as mentioned above, the process temperature for forming the composite dielectric layer 410a is high (700° C. or higher for the diamond layer 414a and 850° C. or higher for the buffer layer BUF). As a result, it is difficult to form the diamond layer 414a by simple deposition of the diamond material within the thermal budget constraints given by BEOL process. That is, a high temperature process is required to be performed to grow the diamond layer 414a; however, the high growth temperature of the diamond layer 414a exceeds the temperature limits of BEOL processes and is not compatible with BEOL process. On the contrary, as shown FIG. 1D to FIG. 1J, by first growing the diamond layer 414a on a separated carrier substrate C and subsequently transferring the diamond layer 414a onto the signal transmission structure 300, the diamond layer 414a can be integrated into the subsequently formed integrated circuit 10 while being compatible with the BEOL thermal budget.

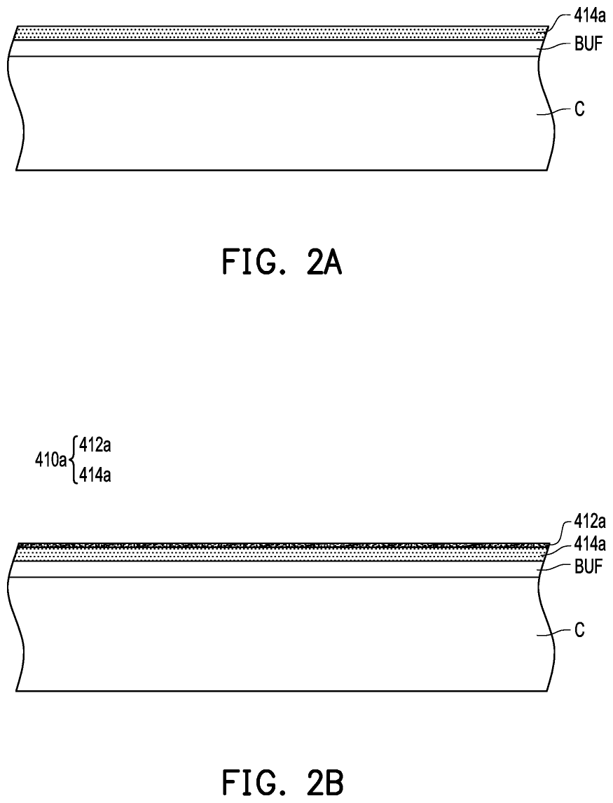

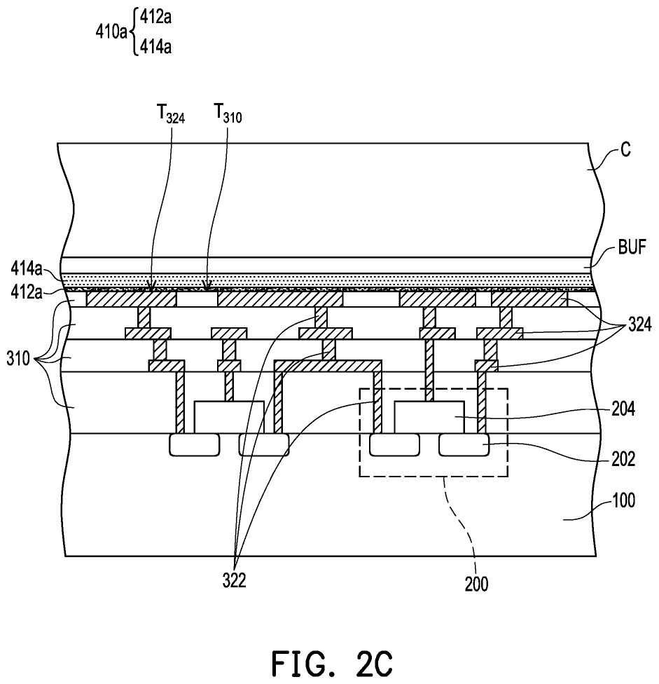

It should be noted that the growth and transfer of the composite dielectric layer 410a shown in FIG. 1D to FIG. 1J merely serves as an exemplary illustration, and the disclosure is not limited thereto. In some alternative embodiments, the composite dielectric layer 410a may be grown and transferred onto the signal transmission structure 300 through other processes. For example, another process for growing and transferring the composite dielectric layer 410a onto the signal transmission structure 300 will be discussed below in conjunction with FIG. 2A to FIG. 2C.

FIG. 2A to FIG. 2C are schematic cross-sectional views illustrating intermediate stages of a manufacturing process of an integrated circuit 10 in accordance with some alternative embodiments of the disclosure. Referring to FIG. 2A, a carrier substrate C is provided. The carrier substrate C in FIG. 2A is similar to the carrier substrate C in FIG. 1D, so the detailed description thereof is omitted herein. In some embodiments, a buffer layer BUF is formed on the carrier substrate C. In some, the buffer layer BUF in FIG. 2A is similar to the buffer layer BUF in FIG. 1D, so the detailed description thereof is omitted herein.

After the buffer layer BUF is formed on the carrier substrate C, a diamond layer 414a is grown on the buffer layer BUF and the carrier substrate C. In some embodiments, the diamond layer 414a is formed on the buffer layer BUF and the carrier substrate C through CVD, MPCVD, or the like. In some embodiments, the process temperature for growing the diamond layer 414a is 700° C. or higher. In some embodiments, the diamond layer 414a is considered to be heteroepitaxial grown on the buffer layer BUF and the carrier substrate C. In some embodiments, the buffer layer BUF is able to effectively improve the quality of the diamond layer 414a formed thereon. For example, as compared to a scenario without a buffer layer, carbon atoms are able to enter the surface of the buffer layer BUF at a higher molar fraction (for example, 10%) during the growing process of the diamond layer 414a. Therefore, more carbon sources can be provided to form high-density diamond nucleation sites on the surface of the buffer layer BUF, and the epitaxial growth of the diamond layer 414a may be sufficiently improved.

Referring to FIG. 2B, an adhesive layer 412a is formed on the diamond layer 414a. In some embodiments, the adhesive layer 412a in FIG. 2B is similar to the adhesive layer 412a in FIG. 1G, so the detailed description thereof is omitted herein. In some embodiments, after the adhesive layer 412a is formed on the diamond layer 414a, a planarization process is performed on the adhesive layer 412a to reduce a surface roughness thereof. In some embodiments, since both of the adhesive layer 412a and the diamond layer 414a are made of dielectric materials, the adhesive layer 412a and the diamond layer 414a may be collectively referred to as a composite dielectric layer 410a. That is, the composite dielectric layer 410a is grown over the carrier substrate C and the buffer layer BUF.

Referring to FIG. 2C, the structure illustrated in FIG. 1C is combined with the structure illustrated in FIG. 2B. For example, the structure illustrated in FIG. 2B is flipped upside down and is placed onto the structure illustrated in FIG. 1C. That is, the diamond layer 414a, the buffer layer BUF, and the carrier substrate C are attached to the signal transmission structure 300 through the adhesive layer 412a. As illustrated in FIG. 2C, the adhesive layer 412a is in physical contact with the top surface T₃₁₀ of the topmost dielectric layer 310 and the top surfaces T₃₂₄ of the topmost conductive patterns 324. As mentioned above, the surface roughness of the top surfaces T₃₂₄ of the topmost conductive patterns 324 and the surface roughness of the top surface T₃₁₀ of the topmost dielectric layer 310 are less than 1 nm. As such, the adhesive layer 412a is attached to a substantially flat surface. In some embodiments, the material of the dielectric layers 310 is different from the material of the composite dielectric layer 410a. That is, the material of the dielectric layers 310 is different from the material of the adhesive layer 412a and the material of the diamond layer 414a. As such, an interface exits between the composite dielectric layer 410a and the topmost dielectric layer 310. That is, an interface exists between the adhesive layer 412a and the topmost dielectric layer 310.

After the diamond layer 414a is attached to the signal transmission structure 300 through the adhesive layer 312a, the buffer layer BUF and the carrier substrate C are removed to obtain the structure shown in FIG. 1J. In some embodiments, the buffer layer BUF and the carrier substrate C are removed through an etching process, a planarization process, a combination thereof, or the like. After removing the buffer layer BUF and the carrier substrate C, the diamond layer 414a has a substantially flat top surface.

By performing the steps shown in FIG. 2A to FIG. 2C, the composite dielectric layer 410a can be easily grown and transferred onto the signal transmission structure 300. In some embodiments, the signal transmission structure 300 and the composite dielectric layer 410a are considered as formed during BEOL process. Conventionally, the thermal budget (i.e., the process temperature window) for BEOL process is low. However, as mentioned above, the process temperature for forming the composite dielectric layer 410a is high (700° C. or higher for the diamond layer 414a and 850° C. or higher for the buffer layer BUF). As a result, it is difficult to form the diamond layer 414a by simple deposition of the diamond material within the thermal budget constraints given by BEOL process. That is, a high temperature process is required to be performed to grow the diamond layer 414a; however, the high growth temperature of the diamond layer 414a exceeds the temperature limits of BEOL processes and is not compatible with BEOL process. On the contrary, as shown FIG. 2A to FIG. 2C, by first growing the diamond layer 414a on a separated carrier substrate C and subsequently transferring the diamond layer 414a onto the signal transmission structure 300, the diamond layer 414a can be integrated into the subsequently formed integrated circuit 10 while being compatible with the BEOL thermal budget.

Referring to FIG. 1J and FIG. 1K, the adhesive layer 412a and the diamond layer 414a are patterned to form a plurality of openings OP1 in the adhesive layer 412a and the diamond layer 414a. That is, the openings OP1 are formed in the composite dielectric layer 410a. In some embodiments, the openings OP1 penetrate through the composite dielectric layer 410a. For example, the openings OP1 penetrate through the adhesive layer 412a and the diamond layer 414a to partially expose the underlying conductive patterns 324. That is, the openings OP1 partially expose the topmost conductive patterns 324. In some embodiments, the patterning process of the adhesive layer 412a and the diamond layer 414a includes a photolithography process and an etching process. The etching process includes a dry etching process. For example, the adhesive layer 412a and the diamond layer 414a may be patterned through RIE, ICP etch, ECR etch, NBE, or the like. In some embodiments, oxygen may be used as an etching gas during the dry etching process.

Referring to FIG. 1L, a conductive material (not shown) is deposited into the openings OP1 to form a plurality of conductive vias 422. For example, the conductive material is conformally formed on the composite dielectric layer 410a. In some embodiments, the conductive material also fills up the openings OP1. In some embodiments, the conductive material includes aluminum, titanium, copper, nickel, tungsten, or alloys thereof. In some embodiments, the conductive material is deposited into the openings OP1 through PVD, ion beam deposition (IBD), CVD, ALD, molecular beam epitaxy (MBE), electro-chemical plating (ECP), electroless deposition (ELD), or the like. Thereafter, a planarization process is performed on the conductive material until the diamond layer 414a is revealed, so as to form the conductive vias 422 in the openings OP1. In some embodiments, the planarization process includes a mechanical grinding process, a CMP process, or the like. After the planarization process, top surfaces T₄₂₂ of the conductive vias 422 are coplanar with a top surface T₄₁₄ₐ of the diamond layer 414a. In other words, the composite dielectric layer 410a laterally encapsulates the conductive vias 422 and exposes the top surfaces T₄₂₂ of the conductive vias 422. In some embodiments, the planarization process reduces a surface roughness of the top surfaces T₄₂₂ of the conductive vias 422 and a surface roughness of the top surface T₄₁₄ₐ of the diamond layer 414a to less than 1 nm.

Referring to FIG. 1M, a composite dielectric layer 410b is formed on the composite dielectric layer 410a and the conductive vias 422. In some embodiments, the composite dielectric layer 410b includes an adhesive layer 412b and a diamond layer 414b disposed on the adhesive layer 412b. The adhesive layer 412b and the diamond layer 414b in FIG. 1M are respectively similar to the adhesive layer 412a and the diamond layer 414a in FIG. 1G, so the detailed descriptions thereof are omitted herein. In some embodiments, the composite dielectric layer 410b may be grown and transferred onto the composite dielectric layer 410a and the conductive vias 422 through steps similar to the steps shown in FIG. 1D to FIG. 1J or the steps shown in FIG. 2A to FIG. 2C.

Referring to FIG. 1M and FIG. 1N, the adhesive layer 412b and the diamond layer 414b are patterned to form a plurality of openings OP2 in the adhesive layer 412b and the diamond layer 414b. That is, the openings OP2 are formed in the composite dielectric layer 410b. In some embodiments, the openings OP2 penetrate through the composite dielectric layer 410b. For example, the openings OP2 penetrate through the adhesive layer 412b and the diamond layer 414b to expose the underlying conductive vias 422. In some embodiments, the openings OP2 also partially exposes the underlying composite dielectric layer 410a. In some embodiments, the patterning process of the adhesive layer 412b and the diamond layer 414b includes a photolithography process and an etching process. The etching process includes a dry etching process. For example, the adhesive layer 412b and the diamond layer 414b may be patterned through RIE, ICP etch, ECR etch, NBE, or the like. In some embodiments, oxygen may be used as an etching gas during the dry etching process.

Referring to FIG. 1O, a conductive material (not shown) is deposited into the openings OP2 to form a plurality of conductive patterns 424. For example, the conductive material is conformally formed on the composite dielectric layer 410b. In some embodiments, the conductive material also fills up the openings OP2. In some embodiments, the conductive material includes aluminum, titanium, copper, nickel, tungsten, or alloys thereof. In some embodiments, the conductive material is deposited into the openings OP2 through PVD, IBD, CVD, ALD, MBE, ECP, ELD, or the like. Thereafter, a planarization process is performed on the conductive material until the diamond layer 414b is revealed, so as to form the conductive patterns 424 in the openings OP2. In some embodiments, the planarization process includes a mechanical grinding process, a CMP process, or the like. After the planarization process, top surfaces T₄₂₄ of the conductive patterns 424 are coplanar with a top surface T_{414b} of the diamond layer 414b. In other words, the composite dielectric layer 410b laterally encapsulates the conductive patterns 424 and exposes the top surfaces T₄₂₄ of the conductive patterns 424. In some embodiments, the planarization process reduces a surface roughness of the top surfaces T₄₂₄ of the conductive patterns 424 and a surface roughness of the top surface T_{414b} of the diamond layer 414b to less than 1 nm.

As illustrated in FIG. 1O, each of the conductive patterns 424 penetrates through one of the composite dielectric layers (i.e., the composite dielectric layer 410b) while each of the conductive vias 422 penetrates through another one of the composite dielectric layers (i.e., the composite dielectric layer 410a). For example, each of the conductive patterns 424 penetrates through one of the adhesive layers (i.e., the adhesive layer 412b) and one of the diamond layers (i.e., the diamond layer 414b) while each of the conductive vias 422 penetrates through another one of the adhesive layers (i.e., the adhesive layer 412a) and another one of the diamond layers (i.e., the diamond layer 414a).

Referring to FIG. 1P, the steps shown in FIG. 1J to FIG. 1O are repeated couple times to form a heat dissipation structure 400 on top of the signal transmission structure 300. In some embodiments, the heat dissipation structure 400 includes a plurality of composite dielectric layers 410a, 410b, 410c, 410d, 410e and a plurality of conductive features 420. In some embodiments, the composite dielectric layers 410a, 410b, 410c, 410d, and 410e are stacked on one another. For example, the adjacent composite dielectric layers 410a, 410b, 410c, 410d, and 410e are in physical contact with each other. In some embodiments, the composite dielectric layer 410c includes an adhesive layer 412c and a diamond layer 414c disposed on the adhesive layer 412c, the composite dielectric layer 410d includes an adhesive layer 412d and a diamond layer 414d disposed on the adhesive layer 412d, and the composite dielectric layer 410e includes an adhesive layer 412e and a diamond layer 414e disposed on the adhesive layer 412e. The adhesive layers 412c, 412d, 412e and the diamond layers 414c, 414d, 414e in FIG. 1P are respectively similar to the adhesive layer 412a and the diamond layer 414a in FIG. 1G, so the detailed descriptions thereof are omitted herein. As illustrated in FIG. 1P, the adhesive layers 412a, 412b, 412c, 412d, 412e and the diamond layers 414a, 414b, 414c, 414d, 414e are alternately stacked on one another above the dielectric layers 310.

In some embodiments, the conductive features 420 include the conductive vias 422 and the conductive patterns 424. As illustrated in FIG. 1P, the conductive features 420 are embedded in the composite dielectric layers 410a, 410b, 410c, 410d, and 410e. As illustrated in FIG. 1P, the conductive vias 422 are embedded in the composite dielectric layers 410a, 410c, and 410e. On the other hand, the conductive patterns 424 are embedded in the composite dielectric layers 410b and 410d. For example, the conductive vias 422 are embedded in the adhesive layers 412a, 412c, 412e and the diamond layers 414a, 414c, 414e while the conductive patterns 424 are embedded in the adhesive layers 412b, 412d and the diamond layers 414b, 414d. In some embodiments, the conductive patterns 424 extend horizontally. Meanwhile, the conductive vias 422 extend vertically to connect the conductive patterns 424 located at different level heights. In other words, the conductive patterns 424 are electrically connected to one another through the conductive vias 422. In some embodiments, the conductive vias 422 and the conductive patterns 424 penetrate through different composite dielectric layers 410a, 410b, 410c, 410d, and 401e. For example, the conductive vias 422 penetrate through the corresponding composite dielectric layers 410a, 410c, and 410e while the conductive patterns 424 penetrate through the corresponding composite dielectric layers 410b and 410d. As illustrated in FIG. 1P, a top surface of each of the diamond layers 414a, 414b, 414c, 414d, and 414e is coplanar with a top surface of the corresponding conductive feature 420. Meanwhile, a top surface of each of the adhesive layers 412a, 412b, 412c, 412d, and 412e is located at a level height lower than that of the top surface of the corresponding conductive feature 420.

In some embodiments, since the diamond layers 414a, 414b, 414c, 414d, and 414e are made of diamond and are grown with a process temperature of 700° C. or higher, a thermal conductivity of the diamond layers 414a, 414b, 414c, 414d, and 414e are high. For example, the thermal conductivity of the diamond layers 414a, 414b, 414c, 414d, and 414e is 600 W/(m·K) or higher. As such, heat generated during the operation of the subsequently formed integrated circuit 10 may be sufficiently dissipated by the diamond layers 414a, 414b, 414c, 414d, and 414e. Therefore, in some embodiments, the diamond layers 414a, 414b, 414c, 414d, and 414e may be referred to as heat dissipation layers. With the integration of these heat dissipation layers (i.e., the diamond layers 414a, 414b, 414c, 414d, and 414e), the performance and the lifetime of the subsequently formed integrated circuit 10 may be sufficiently improved.

In some embodiments, the heat dissipation structure 400 is in physical contact with the signal transmission structure 300. For example, the topmost dielectric layer 310 of the signal transmission structure 300 is in physical contact with the bottommost adhesive layer (i.e., the adhesive layer 412a) of the heat dissipation structure 400. Meanwhile, the bottommost conductive features 420 (i.e., the bottommost conductive vias 422) of the heat dissipation structure 400 are in physical contact with the topmost conductive features 320 (i.e., the topmost conductive patterns 324) of the signal transmission structure 300. In other words, the conductive features 420 of the heat dissipation structure 400 are electrically connected to the conductive features 320 of the signal transmission structure 300. For example, the conductive structures 322, the conductive patterns 324, the conductive vias 422, and the conductive patterns 424 are electrically connected to one another. In some embodiments, the conductive features 420 are electrically connected to the transistors 200 through the conductive features 320.

Since the conductive features 420 of the heat dissipation structure 400 are electrically connected to the conductive features 320 of the signal transmission structure 300, other than dissipating heat, the heat dissipation structure 400 also serves the function of signal transmission.

In some embodiments, the signal transmission structure 300 and the heat dissipation structure 400 are collectively referred to as an interconnect structure INT. That is, the interconnect structure INT is disposed on the semiconductor substrate 100. As illustrated in FIG. 1P, the transistors 200 are partially embedded in the interconnect structure INT. For example, the gate electrodes 204 of the transistors 200 are embedded in the signal transmission structure 300 of the interconnect structure INT.

It should be noted that the number of the composite dielectric layers 410a, 410b, 410c, 410d, 410e, the number of the conductive vias 422, and the number of the conductive patterns 424 illustrated in FIG. 1P are merely for illustrative purposes, and the disclosure is not limited thereto. In some alternative embodiments, fewer or more layers of the composite dielectric layers 410a, 410b, 410c, 410d, 410e, the conductive vias 422, and the conductive patterns 424 may be formed depending on the circuit design.

Referring to FIG. 1Q, a plurality of under-bump metallurgy (UBM) patterns 500 is formed on the heat dissipation structure 400. For example, the UBM patterns 500 are formed on the composite dielectric layer 410e and the topmost conductive vias 422. In some embodiments, the UBM patterns 500 are in physical contact with the topmost conductive vias 422 to render electrical connection with the interconnect structure INT. In some embodiments, the UBM patterns 500 are formed by a sputtering process, a PVD process, a plating process, or the like. In some embodiments, the UBM patterns 500 are made of aluminum, titanium, copper, tungsten, and/or alloys thereof.

After the UBM patterns 500 are formed on the heat dissipation structure 400, a plurality of conductive terminals 600 is disposed on the UBM patterns 500. In some embodiments, the conductive terminals 600 are attached to the UBM patterns 500 through a solder flux. In some embodiments, the conductive terminals 600 are, for example, solder balls, ball grid array (BGA) balls, or controlled collapse chip connection (C4) bumps. In some embodiments, the conductive terminals 600 are made of a conductive material with low resistivity, such as Sn, Pb, Ag, Cu, Ni, Bi, or an alloy thereof.

Thereafter, a singulation process is performed on the heat dissipation structure 400, the signal transmission structure 300, and the semiconductor substrate 100 to obtain a plurality of integrated circuits 10. In some embodiments, the singulation process typically involves dicing with a rotation blade and/or a laser beam. In other words, the singulation process includes a laser cutting process, a mechanical cutting process, a laser grooving process, other suitable processes, or a combination thereof.

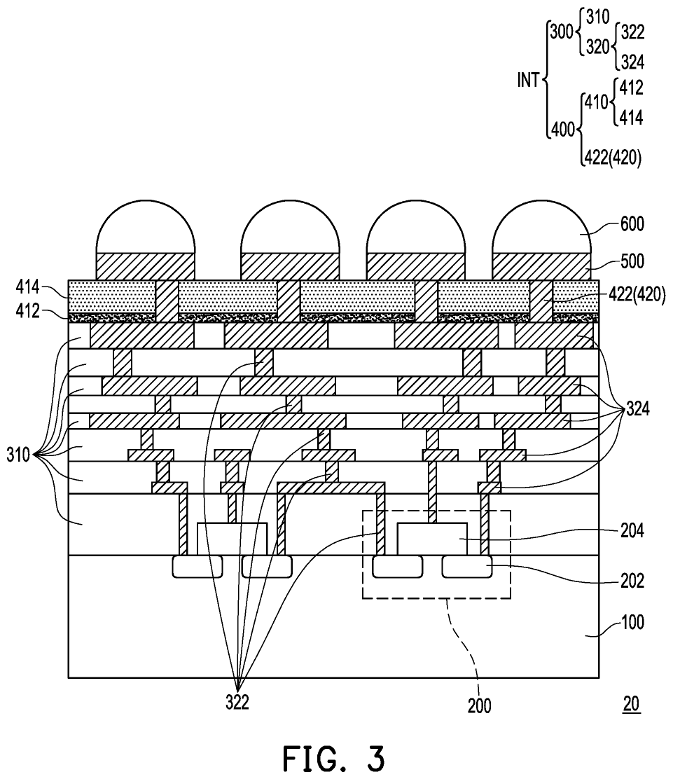

FIG. 3 is a schematic cross-sectional view of an integrated circuit 20 in accordance with some alternative embodiments of the disclosure. Referring to FIG. 3, the integrated circuit 20 in FIG. 3 is similar to the integrated circuit 10 in FIG. 1Q, so similar elements are denoted by the same reference numeral and the detailed descriptions thereof are omitted herein. The difference between the integrated circuit 20 in FIG. 3 and the integrated circuit 10 in FIG. 1Q is that the heat dissipation structure 400 in the integrated circuit 20 of FIG. 3 only includes one composite dielectric layer 410. Moreover, the conductive features 420 of the heat dissipation structure 400 only includes conductive vias 422. In some embodiments, the composite dielectric layer 410 includes an adhesive layer 412 and a diamond layer 414 disposed on the adhesive layer 412. The adhesive layer 412 and the diamond layer 414 in FIG. 3 are respectively similar to the adhesive layer 412a and the diamond layer 414a in FIG. 1G, so the detailed descriptions thereof are omitted herein. Meanwhile, the conductive vias 422 in FIG. 3 are similar to the conductive vias 422 in FIG. 1L, so the detailed descriptions thereof are omitted herein. In some embodiments, the composite dielectric layer 410 may be transferred onto the signal transmission structure 300 through steps similar to the steps shown in FIG. 1D to FIG. 1J or the steps shown in FIG. 2A to FIG. 2C. As such, by first growing the diamond layer 414 on a separated carrier substrate and subsequently transferring the diamond layer 414 onto the signal transmission structure 300, the diamond layer 414 can be integrated into the integrated circuit 20 while being compatible with the BEOL thermal budget. Moreover, with the integration of the heat dissipation layer (i.e., the diamond layer 414), the performance and the lifetime of the integrated circuit 20 may be sufficiently improved.

In accordance with some embodiments of the disclosure, an integrated circuit includes a semiconductor substrate and an interconnect structure. The interconnect structure is disposed on the semiconductor substrate. The interconnect structure includes a signal transmission structure and a heat dissipation structure. The heat dissipation structure is disposed on the signal transmission structure and includes a composite dielectric layer and first conductive features. The composite dielectric layer includes an adhesive layer and a diamond layer disposed on the adhesive layer. The first conductive features are embedded in the composite dielectric layer.

In accordance with some alternative embodiments of the disclosure, an integrated circuit includes a semiconductor substrate and an interconnect structure. The interconnect structure is disposed on the semiconductor substrate. The interconnect structure includes dielectric layers, adhesive layers, first conductive patterns, first conductive vias, second conductive patterns, and second conductive vias. The adhesive layers and the heat dissipation layers are alternately stacked on one another above the dielectric layers. The first conductive patterns and the first conductive vias are embedded in the dielectric layers. The second conductive patterns and the second conductive vias are embedded in the adhesive layers and the heat dissipation layers. The first conductive patterns, the first conductive vias, the second conductive patterns, and the second conductive vias are electrically connected to one another.

In accordance with some embodiments of the disclosure, a manufacturing method of an integrated circuit includes at least the following steps. A semiconductor substrate is provided. An interconnect structure is formed on the semiconductor substrate. The interconnect structure is formed by at least the following steps. A signal transmission structure is formed on the semiconductor substrate. A heat dissipation structure is formed on the signal transmission structure. The heat dissipation structure is formed by at least the following steps. A composite dielectric layer is grown on a carrier substrate. The composite dielectric layer includes a diamond layer and an adhesive layer disposed on the diamond layer. The composite dielectric layer is transferred onto the signal transmission structure. First conductive features are formed in the composite dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a semiconductor substrate; and
an interconnect structure disposed on the semiconductor substrate, comprising:
a signal transmission structure; and
a heat dissipation structure disposed on the signal transmission structure, comprising:
a composite dielectric layer, comprising an adhesive layer and a diamond layer disposed on the adhesive layer; and
first conductive features embedded in the composite dielectric layer.

2. The integrated circuit of claim 1, wherein the signal transmission structure comprises:
dielectric layers, wherein a material of the dielectric layers is different from materials of the composite dielectric layer; and
second conductive features embedded in the dielectric layers.

3. The integrated circuit of claim 2, further comprising transistors disposed on the semiconductor substrate, wherein the first conductive features are electrically connected to the transistors through the second conductive features.

4. The integrated circuit of claim 2, wherein a bottommost first conductive feature is in physical contact with a topmost second conductive feature.

5. The integrated circuit of claim 2, wherein a topmost dielectric layer is in physical contact with a bottommost adhesive layer.

6. The integrated circuit of claim 2, wherein a number of the dielectric layers is four or more.

7. The integrated circuit of claim 1, wherein a top surface of each of the diamond layers is coplanar with a top surface of the corresponding first conductive feature.

8. The integrated circuit of claim 1, wherein the first conductive features comprise:
conductive vias extending vertically to penetrate through the composite dielectric layer.

9. An integrated circuit, comprising:
a semiconductor substrate; and
an interconnect structure disposed on the semiconductor substrate, comprising:
dielectric layers;
adhesive layers and heat dissipation layers alternately stacked on one another above the dielectric layers;
first conductive patterns and first conductive vias embedded in the dielectric layers; and
second conductive patterns and second conductive vias embedded in the adhesive layers and the heat dissipation layers, wherein the first conductive patterns, the first conductive vias, the second conductive patterns, and the second conductive vias are electrically connected to one another.

10. The integrated circuit of claim 9, wherein a number of the dielectric layers is four or more.

11. The integrated circuit of claim 9, wherein a material of the dielectric layers is different from a material of the adhesive layer and a material of the heat dissipation layer.

12. The integrated circuit of claim 11, wherein the material of the heat dissipation layer comprises diamond.

13. The integrated circuit of claim 9, wherein each of the second conductive patterns penetrates through one of the adhesive layers and one of the heat dissipation layers, and each of the second conductive vias penetrates through another one of the adhesive layers and another one of the heat dissipation layers.

14. A manufacturing method of an integrated circuit, comprising:
providing a semiconductor substrate; and
forming an interconnect structure on the semiconductor substrate, comprising:
forming a signal transmission structure on the semiconductor substrate; and
forming a heat dissipation structure on the signal transmission structure, comprising:
growing a composite dielectric layer on a carrier substrate, wherein the composite dielectric layer comprises a diamond layer and an adhesive layer disposed on the diamond layer;
transferring the composite dielectric layer onto the signal transmission structure; and
forming first conductive features in the composite dielectric layer.

15. The method of claim 14, wherein growing the composite dielectric layer and transferring the composite dielectric layer comprise:
growing a sacrificial diamond material layer on the carrier substrate;
patterning the sacrificial diamond material layer to form a sacrificial diamond layer having microneedles thereon;
growing the diamond layer on the microneedles;
forming the adhesive layer on the diamond layer;
attaching the diamond layer, the microneedles, the sacrificial diamond layer, and the carrier substrate to the signal transmission structure through the adhesive layer;
breaking the microneedles to detach a portion of the microneedles, the sacrificial diamond layer, and the carrier substrate from the diamond layer; and
removing the microneedles remained on the diamond layer.

16. The method of claim 14, wherein growing the composite dielectric layer and transferring the composite dielectric layer comprise:
growing the diamond layer on the carrier substrate;
forming the adhesive layer on the diamond layer;
attaching the diamond layer and the carrier substrate to the signal transmission structure through the adhesive layer; and
removing the carrier substrate.

17. The method of claim 14, wherein forming the first conductive features in the composite dielectric layer comprises:
patterning the diamond layer and the adhesive layer to form openings in the diamond layer and the adhesive layer; and
depositing a conductive material in the openings to form the first conductive features.

18. The method of claim 17, wherein top surfaces of the first conductive features are formed to be coplanar with a top surface of the diamond layer.

19. The method of claim 14, wherein forming the signal transmission structure comprises:
forming dielectric layers on the semiconductor substrate; and
forming second conductive features in the dielectric layers, wherein the first conductive features are electrically connected to the second conductive features.

20. The method of claim 19, wherein a number of the dielectric layers is four or more.
